(19) United States
(12) Patent Application Publication
(10) Pub. No.: US 2005/0199999 A1
(43) Pub. Date: Sep. 15, 2005

(54) Semiconductor device

(75) Inventors: Takaaki Shirasawa, Tokyo (JP); Tsuyoshi Takayama, Fukuoka (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Mitsubishi Denki Kabushiki Kaisha, Tokyo (JP)

(21) Appl. No.: 11/066,140

(22) Filed: Feb. 25, 2005

(30) Foreign Application Priority Data
Mar. 9, 2004 (JP) 2004-065341

(51) Int. Cl. H01L 23/10

(52) U.S. Cl. 257/706

(57) ABSTRACT

One of the aspects of the present invention is to provide a semiconductor device including a semiconductor element or chip, which has a peripheral edge and a central portion and is mounted on an insulating substrate via a conductive bonding layer. At least one peripheral thermal sensor is arranged adjacent the peripheral edge on the semiconductor element, and at least one central thermal sensor is arranged adjacent the central portion on the semiconductor element.

### BACKGROUND OF THE INVENTION

1) Technical field of the Invention

The present invention relates to a semiconductor device, and in particular, relates to the power semiconductor device which can detect solder cracks running in a solder bonding layer, thereby to predict fatal damage thereof.

2) Description of Related Arts

In general, the power semiconductor device (or the power module) is used to supply controlled large current for electrical equipments such as a motor and heater. Thus, failure or damage of the power semiconductor device inhibits supplying the controlled current so that the electrical equipment incorporating the power semiconductor device cannot serve the predetermined functions, possibly leading a fatal problem thereof. Therefore, the power semiconductor device is required to have a fairly high level of reliability.

However, it is almost impossible to manufacture the power semiconductor device which would have no failure forever, no matter how advanced manufacturing technique is used. Rather, in reality, during long-term operations, most of power semiconductor devices may have a problem caused by thermal stress due to Joule heat generated from itself, and by mechanical stress due to oscillation traveling from the electrical equipments incorporating thereof. In particular, a solder crack may run and gradually extend in the bonding layer such as a solder layer used for assembling the power semiconductor device. The solder crack prevents radiation of heat generated from a power semiconductor chip, thereby causing the chip to be overheated and completely damaged. Thus, the power semiconductor device has to be replaced with a new one before the solder crack extends across the solder layer and the semiconductor chip is fatally damaged. There have been proposed several approaches to detect the solder crack before the power semiconductor device is actually damaged.

For example, JPA 7-14948 discloses a power semiconductor module using a thermocouple provided at desired position to keep monitoring the temperature of the bonding member during operation. Also, it discloses that while the crack running in the bonding interface increases the thermal resistance thereof, the extension of the crack is determined by sensing the degree of the increased temperature of the semiconductor element.

The solder crack runs at the bonding interface of the solder layer due to difference of linear expansion coefficients between the insulating substrate and the semiconductor chip and/or between the insulating substrate and the heat sink. Thus, the heat cycle causes more stress to the solder layer at the peripheral edge than at the central portion thereof. Thus, the solder crack at the bonding interface, in general, extends from the peripheral edge and towards the central portion of the solder layer. As above, the thermal resistance of the solder layer is increased at a particular area where the solder crack extends. Therefore, in order to precisely detect that the solder crack begins to run in the solder layer, it is necessary to use a thermal sensor arranged adjacent the peripheral edge of the solder layer where the solder crack is more likely developed. It cannot always be expected that the thermal change due to the crack is detected by the thermal sensor arranged at the desired position as described in the aforementioned publication.

Meantime, the U.S. Pat. No. 5,736,769 discloses a semiconductor device including an insulated gate bipolar transistor (IGBT) having a p-n diode with the forward-voltage characteristics depending on temperature where increased temperature raises the forward-voltage thereof. Also, it discloses a plurality of the p-n diodes connected in series for achieving high accuracy of measurement of temperature so that the insulated gate bipolar transistor is prevented from being overheated. However, it fails to even suggest the positions of the p-n diodes and the solder crack. Thus, according to the '769 patent, the increased temperature of the solder layer due to the solder crack at the local area can hardly be detected.

Also, according to the U.S. Pat. Nos. 6,756,964 and 6,721,313, a semiconductor module including a single temperature sensor on the insulating plate and close to the semiconductor chip is disclosed. The temperature sensor monitors a temperature rise rate (dT/dt), the semiconductor module detects deterioration of the solder layer or malfunction of the drive circuit by determining whether the temperature rise rate falls within a range estimated from the operation commands. For example, deterioration of the solder layer above the insulating plate causes the temperature monitored by the temperature sensor on the insulating plate to be increased more gradually than the normal condition since the heat generated from the semiconductor chip is slowly traveled to the insulating plate. On the other hand, deterioration of the solder layer beneath the insulating plate causes the temperature monitored by the temperature sensor to be increased more quickly than the normal condition since the heat is inhibited to disperse to the radiator fin. However, in this publication, simultaneous deterioration of the solder layers above and beneath the insulating plate would cause the temperature rise rate to be increased in a normal way by offsetting the impacts from the deteriorations in those solder layers, thus no deterioration of the solder layer could not be detected.

### SUMMARY OF THE INVENTION

To address the aforementioned drawbacks, one of the aspects of the present invention is to provide a semiconductor device including a semiconductor element or chip, which has a peripheral edge and a central portion and is mounted on an insulating substrate via a conductive bonding layer. At least one peripheral thermal sensor is arranged adjacent the peripheral edge on the semiconductor element, and at least one central thermal sensor is arranged adjacent the central portion on the semiconductor element.

Further scope of applicability of the present invention will become apparent from the detailed description given herein. However it should be understood that the detailed description and specific examples, while indicating preferred embodiments of the invention, are given by way of illustration only, since various changes and modifications within the sprit and scope of the invention will become apparent to those skilled in the art from this detailed description.

### BRIEF DESCRIPTION OF THE DRAWINGS

The present invention more fully be understood from the detailed description given herein and accompanying drawings which are given by way of illustration only, and thus are not limitative of the present invention.

FIG. 1 is a cross sectional view of the semiconductor device according to Embodiment 1 of the present invention.

FIG. 2 is an enlarged cross sectional view of FIG. 1, illustrating the solder cracks running in the upper and lower solder layers.

FIG. 3A is a top plan view of the semiconductor chip according to Embodiment 1 and FIG. 3B is a block diagram showing the equivalent circuit of FIG. 3A.

FIG. 4 is a graph schematically illustrating the characteristics between the temperature (T) and the forward voltage (V_{F}) of a thermal sensor.

FIG. 5A is a top plan view of the semiconductor chip according to Embodiment 2 and FIG. 5B is a block diagram showing the equivalent circuit of FIG. 5A.

FIG. 6A is a top plan view of the semiconductor chip according to Embodiment 3 and FIG. 6B is a block diagram showing the equivalent circuit of FIG. 6A.

FIG. 7A is a top plan view of the semiconductor chip according to Embodiment 4 and FIG. 7B is a block diagram showing the equivalent circuit of FIG. 7A.

FIG. 8A is a top plan view of the semiconductor chip according to Embodiment 5 and FIG. 8B is a block diagram showing the equivalent circuit of FIG. 8A.

FIG. 9A is a top plan view of the semiconductor chip according to Embodiment 6 and FIG. 9B is a block diagram showing the equivalent circuit of FIG. 9A.

FIG. 10A is a top plan view of the semiconductor chip according to Embodiment 7 and FIG. 10B is a block diagram showing the equivalent circuit of FIG. 10A.

FIG. 11 is a top plan view of the semiconductor chips according to Embodiment 8.

FIG. 12 is a top plan view of the semiconductor chips according to Embodiment 9.

FIG. 13 is a top plan view of the semiconductor chips according to Embodiment 10.

### DETAILED DESCRIPTION OF THE PREFERRED EMBODIMENTS

Referring to the attached drawings, the details of embodiments according to the present invention will be described herein. In those descriptions, although the terminology indicating the directions (for example, “upper” and “lower”) are conveniently used just for clarity, it should not be interpreted that those terminology limit the scope of the present invention.

### Embodiment 1

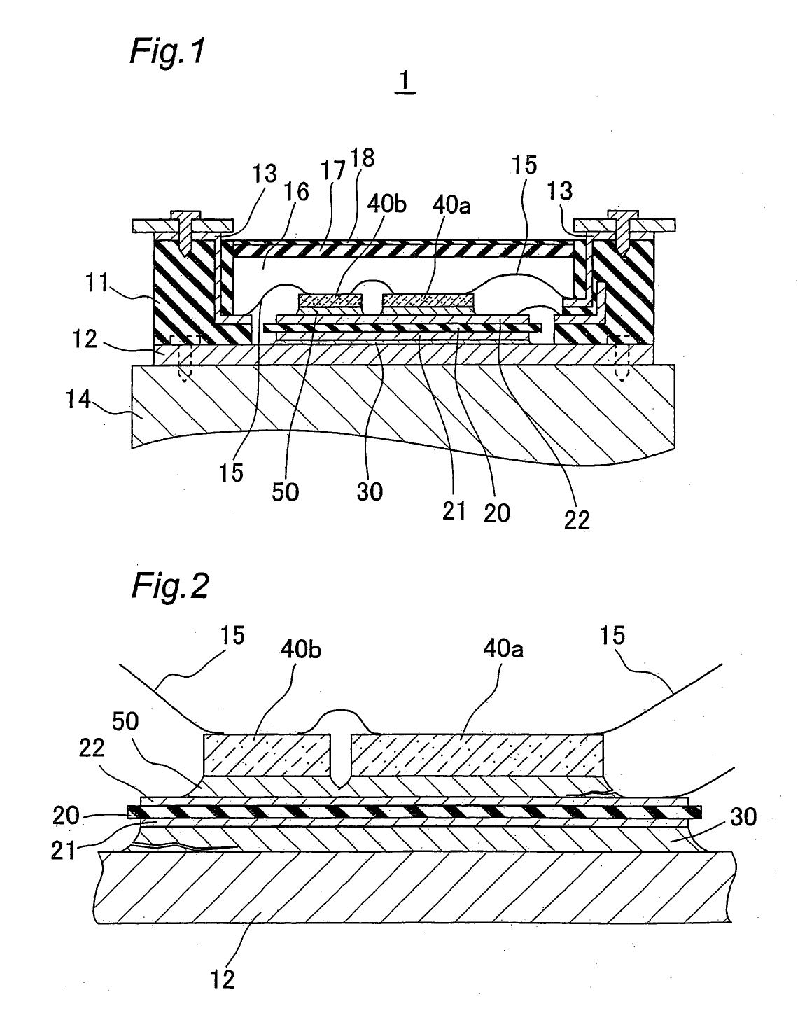

With reference to FIGS. 1 to 4, a power semiconductor device (a power module) according to Embodiment 1 of the present invention will be described herein. In FIG. 1, the power module 1 includes, in general, a casing 11 of insulating material, a metal base plate (heat sink) 12 of good thermal conductivity such as copper, and a plurality of main terminals 13 extending from the upper surface of the casing 11 to the inside of the power module 1. As shown in FIG. 1, the casing 11 is secured on the metal base plate 12, which is secured on a metal radiator fin 14. Also, as clearly illustrated in FIG. 2, within the power module 1, an insulating substrate 20 having metal patterns 21, 22 on top and bottom surfaces thereof is bonded on the metal base plate 12 via a conductive bonding layer such as the solder layer 30. In addition, there is at least one semiconductor element (including for example, an insulating gate bipolar transistor (IGBT) 40a and/or an free wheel diode (FWD) 40b) bonded on the insulating substrate 20 via another conductive bonding layer such as the solder layer 50. The solder layers 30, 50 will conveniently be referred herein to as the “lower solder layer (first conductive bonding layer)” and the “upper solder layer (second conductive bonding layer)”, respectively.

Thus, the lower metal pattern 21 of the insulating substrate 20 is fixed on the metal base plate 12 through the lower solder layer 30, and the semiconductor elements (semiconductor chips) 40a, 40b are bonded on the upper metal pattern 22 of the insulating substrate 20 through the upper solder layer 50.

As shown in FIG. 1, a plurality of metal wires 15 such as aluminum wires are used for electrical connection between the main terminal 13 and each one of the semiconductor chips 40a, 40b and between both of the semiconductor chips 40a, 40b. Further, silicone gel 16 is filled up over the semiconductor chips 40a, 40b and the insulating substrate 20 for protection of the semiconductor chips 40a, 40b and the metal wires 15, of which hatching is eliminated for clear illustration. Lastly, epoxy resin 17 is applied on the silicone gel 16, on which a lid 18 is positioned.

In the following description, the semiconductor chip may be either one of the IGBT 40a and FWD 40b, thus collectively, the terminology of the “semiconductor element or chip 40” may often used to refer either one of them.

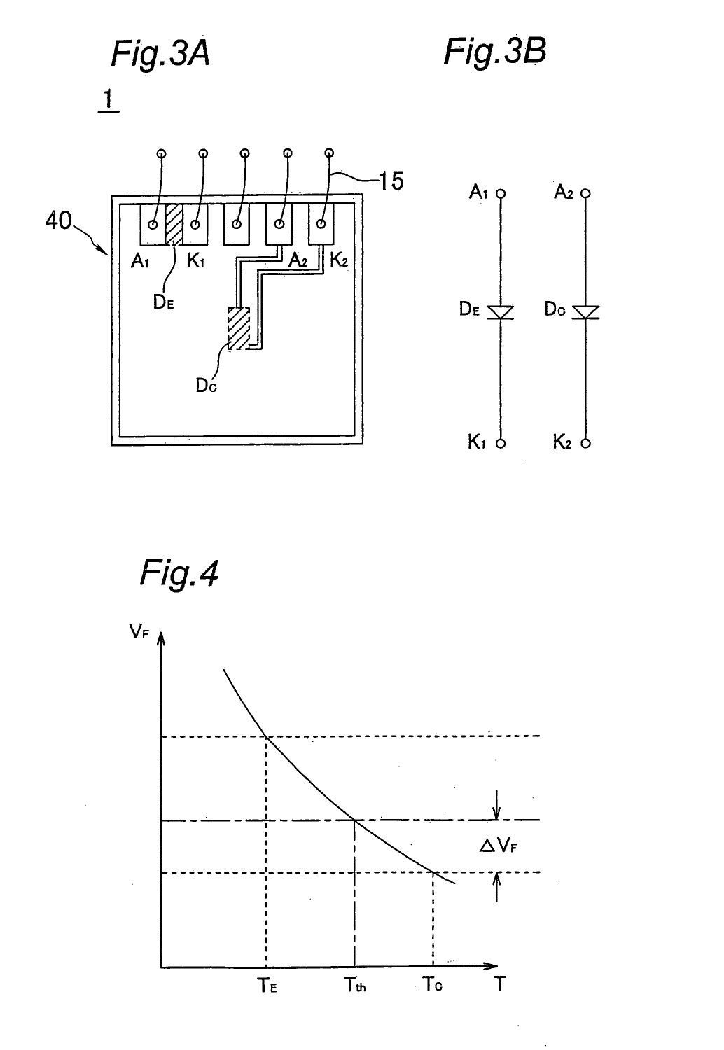

As illustrated in FIG. 3A, the semiconductor chip 40 of Embodiment 1 includes at least one edge diode D_{E}(peripheral thermal sensor) arranged adjacent the peripheral edge, and at least one central diode D_{C}(central thermal sensor) arranged adjacent the central portion on the semiconductor chip 40. In FIG. 3B, the edge diode D_{E} between a first anode terminal pad A₁ and a first cathode terminal pad K₁ is connected in parallel with the central diode D_{C} between a first anode terminal pad A₂ and a first cathode terminal pad K₂. Two of constant current sources of an external control circuit (not shown) are used to supply power to the edge diode D_{E} and the central diode D_{C} through the first anode and cathode terminal pads A₁, K₁ and the second anode and cathode terminal pads A₂, K₂, respectively, so that the constant level of current is flown through the diodes D_{E}, D_{C} during operation. Preferably, each of the diodes D_{E}, D_{C} has the same voltage-current characteristics (V_{F}−I_{F} characteristics), in which the forward voltage is 2.5V at the forward current of 0.2 mA at room temperature of 25 degrees centigrade.

In general, it has been well known that as ambient temperature is increased, the forward-voltage V_{F} is decreased, thus the ambient temperature can be detected by measuring the forward-voltage V_{F}. Also, the present inventors have revealed that edge temperature T_{E} sensed by the edge diode D_{E} is less than central temperature T_{C} measured by the central diode D_{C} approximately by 15-20 degrees centigrade during normal operation of the power semiconductor device 1.

Meanwhile, as the operation time of the power semiconductor device 1 passes, the solder crack runs at the bonding interface of the upper solder layer 50 between the semiconductor chip 40 and the insulating substrate 20 and gradually extends from the peripheral edge to the central portion thereof, as illustrated in FIG. 2. Thus, in the semiconductor chip 40 having a rectangular configuration shown in FIG. 3, the crack in the upper solder layer 50 is creeping from the corners to the central portion of the solder layer 50. Once the crack is formed at a local area in the solder layer 50, the thermal resistance at such a local area is increased, thereby inhibiting radiation of heat generated from the semiconductor chip 40. Thus, the semiconductor chip 40 is more heated especially above the local area of the upper solder layer 50 where the solder crack extends.

In other words, during operation of the power semiconductor device 1, while the temperature difference between the edge temperature T_{E} and the central temperature T_{C} is kept constant with no crack running in the solder layer 50, the edge temperature T_{E} is approaching to the central temperature T_{C} as the crack extends across the solder layer 50. Therefore, the solder crack can be detected at the peripheral edge of the solder layer 50 by monitoring the edge temperature T_{E} and the central temperature T_{C} and to determine whether the temperature difference is less than a threshold value Tₜₕ (T_{C}−T_{E}<Tₜₕ).

As above, the external control circuit (not shown) can detect the solder crack at the peripheral edge of the solder layer 50 by monitoring the gap of the forward-voltages V_{F} between the edge diode D_{E} and the central diode D_{C} in a simple and convenient manner. The external control circuit may alarm the user for the necessity of replacement of the power semiconductor device 1 or safely suspend the operation of the electrical equipment incorporating the power semiconductor device 1, before the semiconductor chip 40 is overheated to cause the fatal damage.

According to one of the aspects of the present invention, the solder crack is detected based upon the relative temperature difference, i.e., how the edge temperature T_{E} has approached to the central temperature T_{C}. Thus, since the present detection mechanism of the solder crack is not based upon the absolute values of the edge temperature T_{E} and the central temperature T_{C}, it can be insusceptible to the operation condition of the power semiconductor device 1, thereby allowing the solder crack to be inspected in a more precise manner.

### Embodiment 2

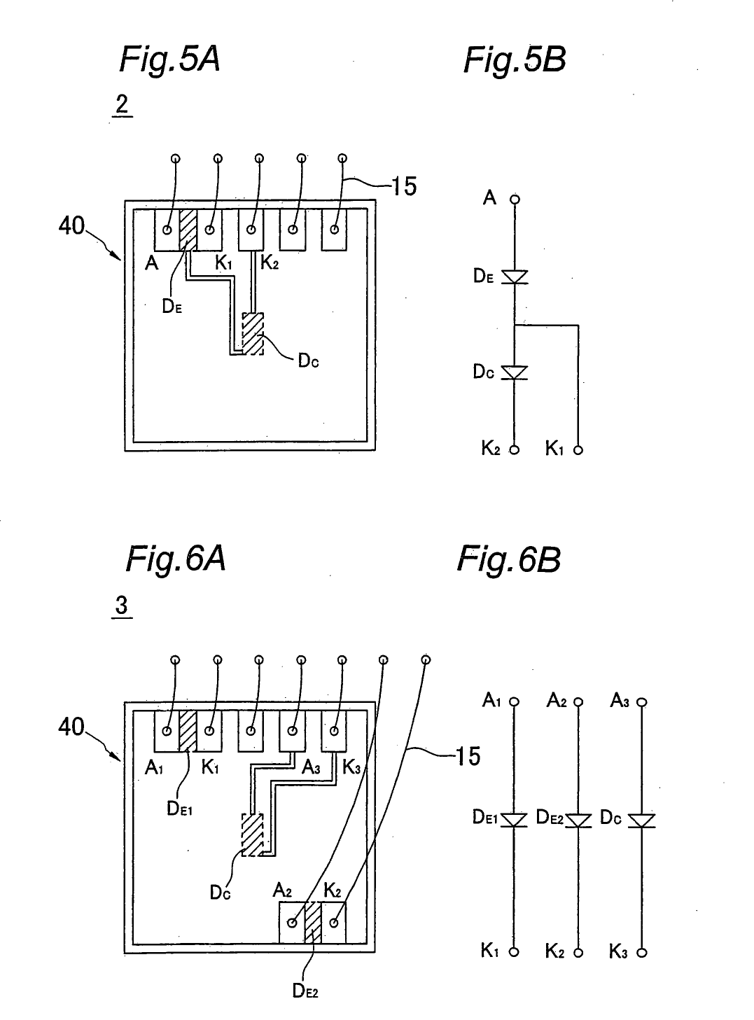

Referring to FIGS. 5A and 5B, another power module according to Embodiment 2 of the present invention will be described herein. The power module 2 of Embodiment 2 is similar to that of Embodiment 1 except that the edge diode D_{E} and the central diode D_{C} are connected in series to each other. Therefore, the duplicate description for the similar structure of Embodiment 2 will be eliminated.

As illustrated in FIGS. 5A and 5B, the edge diode D_{E} and the central diode D_{C} of Embodiment 0.2 are connected in series to each other. Thus, a single constant current source is connected between the common anode terminal pad A and the cathode terminal pad K₂ so as to flow the constant current therebetween. Also, another cathode terminal pad K₁ is provided to detect the potential between the edge diode D_{E} and the central diode D_{C}. Therefore, the semiconductor device 2 of Embodiment 2 uses only one constant current source and three terminal pads for detection of the forward voltage of the edge diode D_{E} and the central diode D_{C}, while Embodiment 1 requires two pairs of the constant current sources and two pairs (four) of terminal pads. Thus, according to Embodiment 2, the number of the required constant current sources can be reduced so as to simplify the external control circuit in comparison with that of Embodiment 1. One of the required terminal pads can be eliminated to downsize the semiconductor chip 40 or to increase the effective area of the semiconductor chip 40. Also, similar to Embodiment 1, the power module 2 according to Embodiment 2 can precisely detect the solder crack running at the peripheral edge in the upper solder layer 50.

### Embodiment 3

Referring to FIGS. 6A and 6B, another power module according to Embodiment 3 of the present invention will be described herein. The power module 3 of Embodiment 3 is similar to that of Embodiment 1 except that a plurality (two in FIGS. 6A and 6B) of the edge diodes D_{E} are provided at the peripheral edge of the semiconductor chip. Therefore, the duplicate description for the similar structure of Embodiment 3 will be eliminated.

According to Embodiment 3, a first edge diode D_{E1} is connected between the anode terminal pad A₁ and the cathode terminal pad K₁, a second edge diode D_{E2} is connected between the anode terminal pad A₂ and the cathode terminal pad K₂, and the central diode D_{C} is connected between the anode terminal pad A₃ and the cathode terminal pad K₃, as illustrated in FIGS. 6A and 6B.

Also, the first and second edge diodes D_{E1}, D_{E2} are preferably arranged at the peripheral edges substantially diagonally opposite to each other, i.e., at upper-left corner and lower-right corners on the semiconductor chip 40 as shown in FIG. 6A. When the solder crack often runs from the peripheral edge of the upper solder layer 50 as above, it may extend in a diametrical line thereof. Thus, two of the edge diodes D_{E1}, D_{E2} improve accuracy for detecting the change of the edge temperature T_{E}. Further, three or more of the edge diodes would more enhance the accuracy of detection of the solder crack in the upper solder layer 50.

### Embodiment 4

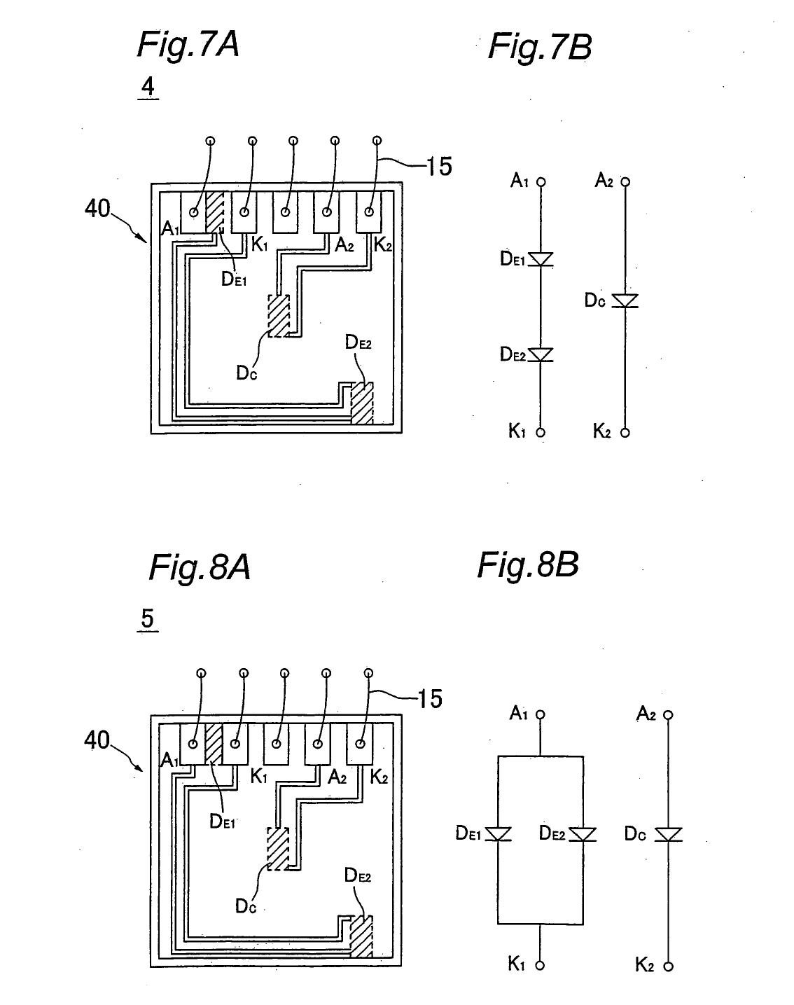

With reference to FIGS. 7A and 7B, another power module according to Embodiment 4 of the present invention will be described herein. The semiconductor device 4 of Embodiment 4 is similar to that of Embodiment 3 except that the first and second edge diodes D_{E1}, D_{E2} are connected in series. Therefore, the duplicate description for the similar structure of Embodiment 4 will be eliminated.

As illustrated in FIGS. 7A and 7B, the first and second edge diodes D_{E1}, D_{E2} are connected in series between the anode terminal pad A₁ and the cathode terminal pad K₁, and also the central diode DC is connected between the anode terminal pad A₂ and the cathode terminal pad K₂.

According to Embodiment 4 shown in FIGS. 7A and 7B, a plurality of the edge diodes arranged at the peripheral edge on the semiconductor chip 40 improves the accuracy for detecting the solder crack as Embodiment 3. Also, Embodiment 4 requires fewer of the constant current sources and terminal pads than Embodiment 3 so as to downsize the semiconductor chip 40 or to increase the effective area thereof.

### Embodiment 5

With reference to FIGS. 8A and 8B, another power module according to Embodiment 5 of the present invention will be described herein. The semiconductor device 5 of Embodiment 5 is similar to that of Embodiment 4 except that the first and second edge diodes D_{E1}, D_{E2} are connected in parallel to each other. Therefore, the duplicate description for the similar structure of Embodiment 5 will be eliminated.

In Embodiment 5 shown in FIGS. 8A and 8B, the first and second edge diodes D_{E1}, D_{E2} are connected in parallel between the anode terminal pad A₁ and the cathode terminal pad K₁, and also the central diode DC is connected between the anode terminal pad A₂ and the cathode terminal pad K₂.

According to Embodiment 5, a plurality of the edge diodes arranged in parallel detects the solder cracks independently at the peripheral edge on the semiconductor chip 40. This is advantage in case where the cracks runs at different portions of the upper solder layer 50. The solder cracks may extend irregularly in the solder layer 50, and solder crack extending in a limited area of the solder layer unlikely causes the semiconductor chip 40 to be overheated and fatally damaged. Rather, such devastating damage may often result from the solder cracks extending from a plurality of separate peripheral areas to the central portion. Thus, since the power module 5 according to Embodiment 5 includes the first and second edge diodes D_{E1}, D_{E2} connected in parallel, it can detect the solder cracks extending from the several peripheral areas in a simple and reliable manner, by normalizing the changes of the edge temperature detected by those edge diodes.

### Embodiment 6

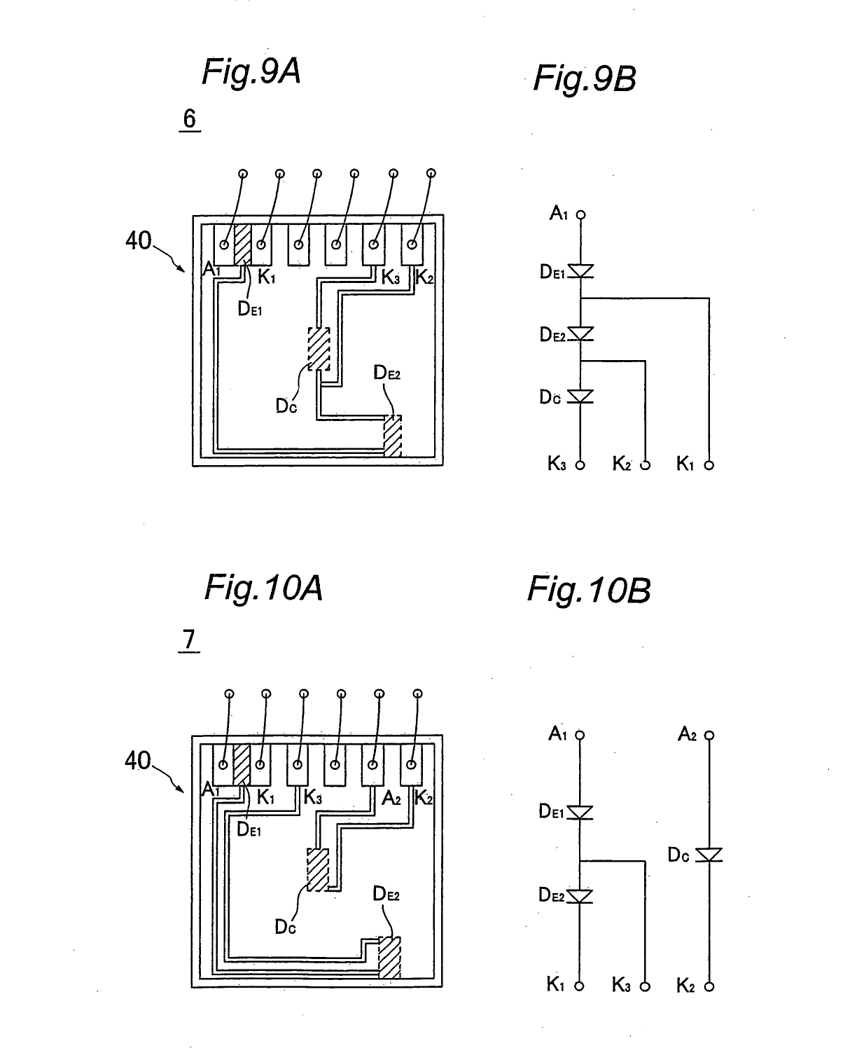

With reference to FIGS. 9A and 9B, another power module according to Embodiment 6 of the present invention will be described herein. The power module 6 of Embodiment 6 is similar to that of Embodiment 2 except that not only the central diode D_{C} but also the second edge diodes D_{E2} are connected in series to the first edge diodes D_{E1}. Therefore, the duplicate description for the similar structure of Embodiment 6 will be eliminated.

In Embodiment 6, the first and second edge diodes D_{E1}, D_{E2} and the central diode D_{C} are connected in series between the anode terminal pad A₁ and the cathode terminal pad K₃. Also, other cathode terminal pads K₁, K₂ are provided to detect the potentials between the first and second edge diodes D_{E1}, D_{E2} and between the second edge diodes D_{E2} and the central diode D_{C}.

Thus, similar to Embodiment 3, since the power module 6 of Embodiment 6 includes a plurality of edge diodes D_{E1}, D_{E2} arranged close to the peripheral edges, it can detect the solder crack in a more accurate manner. Also, comparing to Embodiment 3, it reduces the required constant current sources (three to only one) and the terminal pads (six to four) so as to simplify the external control circuit and downsize the semiconductor chip 40 or to increase the effective area of the semiconductor chip 40.

### Embodiment 7

With reference to FIGS. 10A and 10B, another power module according to Embodiment 7 of the present invention will be described herein. The power module 7 of Embodiment 7 is similar to that of Embodiment 4 except that another terminal pad K₃ is provided between the first and second edge diodes D_{E1}, D_{E2}, for detecting the potential therebetween. Therefore, the duplicate description for the similar structure of Embodiment 7 will be eliminated.

In FIGS. 10A and 10b, the first and second edge diodes D_{E1}, D_{E2} are connected in series between the anode terminal pad A₁ and the cathode terminal pad K₁. Also, the central diode D_{C} is connected between the anode terminal pad A₂ and the cathode terminal pad K₂. In addition, a separate cathode terminal pad K₂ is arranged between the first and second edge diodes D_{E1}, D_{E2}, for sensing the potential therebetween. While according to Embodiment 3, three of constant current sources and three pairs (six) of the terminal pads are used to measure the forwards voltages V_{F} of the first and second edge diodes D_{E1}, D_{E2} and the central diode D_{C}, according to the present embodiment, only two of constant current sources and five of the terminal pads are required for detection of the forwards voltages V_{F}.

Thus, the semiconductor device 7 of Embodiment 7 requires fewer constant current sources so as to simplify the external control circuit, and the terminal pads to downsize the semiconductor chip 40 or to increase the effective area of the semiconductor chip 40, in comparison with Embodiment 3. Nonetheless, the power module 7 can properly detect the solder crack running at the peripheral edges of the upper solder layer 50, as Embodiment 3.

### Embodiment 8

While the power module of the Embodiments 1 through 7 are described for one of the purposes to detect the solder crack in the upper solder layer 50, the power module of the Embodiments 8 through 10 principally are described for another one of the purposes to detect solder crack running at the peripheral edges of lower solder layer 30.

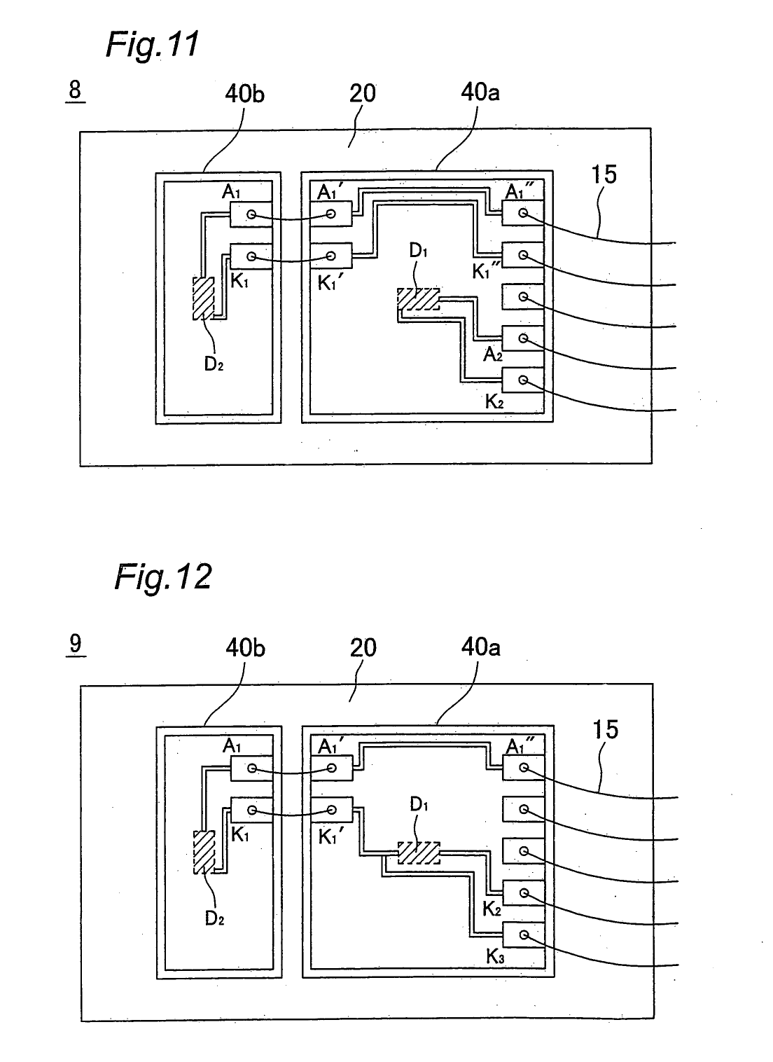

With reference to FIGS. 2 and 11, a power module (power semiconductor device) according to Embodiment 8 of the present invention will be described herein. In Embodiment 1, the single semiconductor chip 40 of the power module 1 is discussed, on which the edge diodes D_{E} and the central diode D_{C} are arranged at the peripheral edge and the central portion, respectively. Meanwhile, the power module 8 of the present embodiment includes at least two semiconductor chips such as the IGBT 40a and the FWD 40b, on which first and second diodes D₁ and D₂ are provided at the central portions, respectively. Besides this point, the power module 8 of Embodiment 8 has the similar structure, of which duplicate description will not be repeated in detail.

As illustrated in FIG. 11, the power module 8 includes the IGBT 40a and the FWD 40b. The first and second diodes D₁, D₂ are arranged at the central portions of the IGBT 40a and the FWD 40b, respectively. Also, the second diode D₂ is connected between anode and cathode terminal pads A₁, K₁ on the FWD 40b, which in turn are connected to anode and cathode terminal pads A₁, K₁ on the IGBT 40a through metal wires and another anode and cathode terminal pads A₁′, K₁′ on the IGBT 40a. Also, the first diode D₁ is connected between anode and cathode terminal pads A₂, K₂ on the FWD 40b.

During operation of the power module 8, since the IGBT 40a produces Joule heat greater than that of the FWD 40b, the temperature T₂ of the FWD 40b sensed by the second diode D₂ is less than the temperature T₁ of the IGBT 40a sensed by the first diode D₁. Therefore, the lower solder layer 30 between the insulating substrate 30 and the metal base plate 12 is exposed to the stress due the difference of the linear expansion coefficients thereof. Also, since the lower solder layer 30 beneath the FWD 40b is more remote from the IGBT 40a as a heat source, it has to take more severe thermal shock (greater degrees of the expansion and shrinkage) and therefore the lower solder layer 30 endure greater stress beneath the FWD 40b than beneath the IGBT 40a. Thus, the solder crack in the lower solder layer 30 runs at the corners of the insulating substrate 20 adjacent the FWD 40B and extends towards the IGBT 40a.

As the solder crack extends to the lower solder layer 30 beneath the central portion of the FWD 40b, the temperature T₂ sensed by the second diode D₂ is increasing to approach towards the temperature T₁ detected by the first diode D₁. Therefore, according to Embodiment 8, the solder crack at the peripheral edges in the lower solder layer 30 can be detected by sensing the temperature difference between the IGBT temperature T₁ and the FWD temperature T₂ to determine whether the temperature difference is less than the predetermined temperature (T₁-T₂<Tₜₕ). Once the external control circuit (not shown) detects the solder crack at the peripheral edges in the lower solder layer 30, it alarms the user for the necessity of replacement of the power semiconductor device or suspends the electrical equipment incorporating the power semiconductor device in a safe manner, before the solder cracks extend across the lower solder layer 30 to cause the semiconductor chip 40 to be overheated and fatally damaged.

According to Embodiment 8, similar to Embodiment 1, the solder cracks are detected based upon how the FWD temperature T₂ approaches the IGBT temperature T₁, i.e., upon the relative temperature difference between the IGBT temperature T₁ and the FWD temperature T₂. Thus, the power module of the present embodiment can properly determine the solder cracks independently on the absolute values of the IGBT temperature T₁ and the FWD temperature T₂, i.e., irrelevant to the operation conditions of the semiconductor device.

### Embodiment 9

Referring to FIG. 12, another power module according to Embodiment 9 of the present invention will be described herein. The power module 9 of Embodiment 9 is similar to that of Embodiment 8 except that the first and second diodes D₁ and D₂ are connected in series to each other. Therefore, the duplicate description for the similar structure of Embodiment 9 will be eliminated.

According to Embodiment 8, two pairs of the constant current sources and two pairs of terminal pads are used to measure the forward voltages V_{F} of the first and second diodes D₁ and D₂. Meantime, according to Embodiment 9, a single constant current source and three of terminal pads are utilized to sense the forward voltages V_{F}. Thus, according to Embodiment 9, the number of the required constant current sources can be reduced to simplify the external control circuit in comparison with Embodiment 8. Also, one of the required terminal pads can be eliminated to downsize the semiconductor chip 40 or to increase the effective area of the semiconductor chip 40.

### Embodiment 10

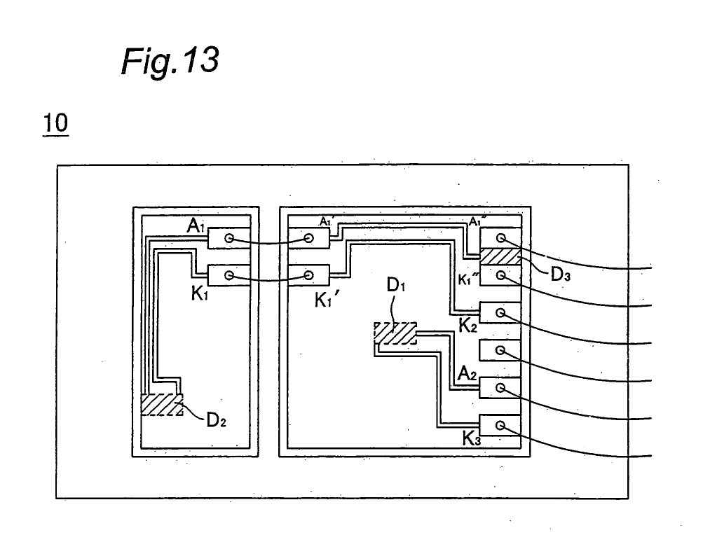

Referring to FIG. 13, another power module according to Embodiment 10 of the present invention will be described herein. The power module 10 of Embodiment 10 is similar to that of Embodiment 8 except that the second diode D₂ is arranged adjacent the peripheral edge of the FWD 40b, and a third diode D₃ is added adjacent the peripheral edge on the IGBT 40a, which is connected in series to the second diode D₂. Therefore, the duplicate description for the similar structure of Embodiment 10 will be eliminated.

As illustrated in FIG. 13, since the second diode D₂ is arranged on the FWD 40b, similar to Embodiment 8, the solder crack in the lower solder layer 40 beneath the corner of the FWD 40b can be properly detected. Also, since the third diode D₃ is arranged adjacent the peripheral edge of the IGBT 40a, similar to Embodiment 1, the solder crack in the upper solder layer 50 beneath the corner of the IGBT 40a can be precisely sensed. Therefore, the power module 8 of Embodiment 8 can determine the solder cracks both in the upper and lower solder layers 30, 50 with such a simple structure.

1. A semiconductor device, comprising:
a semiconductor element having a peripheral edge and a central portion, said semiconductor element being mounted on an insulating substrate via a conductive bonding layer;
at least one peripheral thermal sensor arranged adjacent the peripheral edge on said semiconductor element; and
at least one central thermal sensor arranged adjacent the central portion on said semiconductor element.

2. The semiconductor device according to claim 1,
wherein said peripheral thermal sensor and said central thermal sensor are connected in parallel to each other.

3. The semiconductor device according to claim 1,
wherein said peripheral thermal sensor and said central thermal sensor are connected in series to each other.

4. The semiconductor device according to claim 3, further including a terminal pad between said peripheral thermal sensor and said central thermal sensor.

5. The semiconductor device according to claim 1,
wherein at least two of said peripheral thermal sensors are arranged adjacent the peripheral edges on said semiconductor element.

6. The semiconductor device according to claim 5,
wherein at least two of said peripheral thermal sensors are diagonally opposite to each other on the semiconductor element.

7. The semiconductor device according to claim 5,
wherein at least two of said peripheral thermal sensors are connected in parallel to each other.

8. The semiconductor device according to claim 5,
wherein at least two of said peripheral thermal sensors are connected in series to each other.

9. The semiconductor device according to claim 8, further including a terminal pad between at least two of said peripheral thermal sensors.

10. A semiconductor device, comprising:
an insulating substrate mounted on a heat sink via a first conductive bonding layer;
first and second semiconductor elements mounted on said insulating substrate via a second conductive bonding layer;
at least one first thermal sensor arranged on said first semiconductor element; and
at least one second thermal sensor arranged on said second semiconductor element;
wherein said first semiconductor element generates heat greater than said second semiconductor element.

11. The semiconductor device according to claim 10,
wherein said first and second thermal sensors are connected in parallel to each other.

12. The semiconductor device according to claim 10,
wherein said first and second thermal sensors are connected in series to each other.

13. The semiconductor device according to claim 12, further including a terminal pad between said first and second thermal sensors.

14. The semiconductor device according to claim 10,
said first semiconductor element including a first peripheral thermal sensor and at least one central thermal sensor arranged adjacent the peripheral edge and the central portion thereof, respectively; and
said second semiconductor element including at least one second peripheral thermal sensor arranged adjacent the peripheral edge thereof;
wherein said first and second peripheral thermal sensors are connected in series to each other.

15. The semiconductor device according to claim 14, further including a terminal pad between said first and second peripheral thermal sensors.

16. The semiconductor device according to claim 10,
wherein said first semiconductor element includes an insulated gate bipolar transistor, and second semiconductor element includes a free wheel diode.
